(19) United States
(12) Patent Application Publication
(10) Pub. No.: US 2008/0224714 A1
(43) Pub. Date: Sep. 18, 2008

(54) System and Method of Integrated Circuit Control for in Situ Impedance Measurement

(76) Inventors: Tanit Virutchapunt, AUSTIN, TX (US); Sungjun Chun, Austin, TX (US); Timothy M. Skergan, Austin, TX (US); Roger D. Weekly, Austin, TX (US)

Correspondence Address: IBM CORPORATION (VE);C/O VOLEL EMILE, P. O. BOX 162485, AUSTIN, TX, 78716, US

(21) Appl. No.: 11/685,226

(22) Filed: Mar. 13, 2007

(51) Int. Cl. G01R 27/02

(52) U.S. Cl. 324/602

(57) ABSTRACT

A system and method of integrated circuit control for in situ impedance measurement including a system with a plurality of functional partitions in a clocked logic type integrated circuit, the functional partitions having a communication controller and a modulation gate, the modulation gate receiving a clock signal and a modulation signal and generating a modulated clock signal for the functional partition; at least one of the communication controllers receiving an in-band signal and selectively communicating the in-band signal to the other communication controllers; and at least one of the functional partitions having a modulator, the modulator receiving the clock signal and a modulation control signal and generating the modulation signal.

### TECHNICAL FIELD

The technical field of this disclosure is integrated circuit design and fabrication, particularly, integrated circuit control for in situ impedance measurement.

### BACKGROUND OF THE INVENTION

The design and fabrication of clocked logic type integrated circuits, such as microprocessors, requires determination of an impedance characteristic for each integrated circuit design. The impedance characteristic, i.e., the impedance as a function of frequency, is required so that the performance and power usage of circuits using the integrated circuit can be calculated during the circuit design.

Presently, the impedance characteristic is determined by measuring impedances at a number of different frequencies using test equipment temporarily attached to the integrated circuit. Test leads are soldered to the integrated circuit to provide voltage test points, and an oscilloscope or other voltage measuring device attached to the voltage test points. A pulse generator is attached to the clock input of the integrated circuit. Other logic activity on the integrated circuit is inhibited by applying appropriate signals to the appropriate pins. The impedance can be calculated as a function of the voltage at a given clock input frequency.

Measurements at a number of clock input frequencies are needed to provide a statistically significant sample. The sample typically covers a broad frequency range, such as from 100 kHz to 200 MHz, so that hundreds of measurements are taken. The clock input frequency is set to a desired value, the voltage is measured, and the clock input frequency is set to the next value.

This is repeated over the whole frequency range and takes hours to perform. The impedance characteristic can then be determined from the data collected.

FIG. 1 is a schematic diagram of an existing out-of-band impedance measuring system. The impedance measuring system 20 requires an out-of-band input, i.e., an input from outside the users application or operating system, such as service interface input 22 illustrated here. A control command interface 24 is responsive to the service interface input 22 to control a modulated clock signal 34 provided to the functional partitions 40 of the integrated circuit. A clock signal 26 modulated into the modulated clock signal 34 by passing through a phase locked loop (PLL) 30 and gate 32 under control of the control command interface 24. Other approaches feed the clock signal 26 directly to the gate 32 or modulate the clocks elsewhere in the clock distribution hierarchy. The impedance characteristics of the integrated circuit can be determined by varying the frequency of the modulated clock signal 34. Unfortunately, the service interface input 22 and the control command interface 24 limit the flexibility and range of service access of the user. The service interface input 22 is typically only able to accept a certain protocol and a certain number of predetermined commands, which may not be the commands desired by the user. In addition, specialized hardware is required to make the connection to the control command interface 24.

The present process of impedance characteristic determination is cumbersome and time consuming. The integrated circuit or the circuit board on which the integrated circuit is mounted must be set up in a test stand and temporary leads attached. External hardware, such as the pulse generator and the oscilloscope must be calibrated and attached to the integrated circuit. The pulse generator must be manually advanced over the frequency range and voltage measured via the attached oscilloscope for each frequency.

It would be desirable to have a system and method of integrated circuit control for in situ impedance measurement that would overcome the above disadvantages.

### SUMMARY OF THE INVENTION

The system and method of integrated circuit control for in situ impedance measurement of the present invention provides in-band impedance measurement using readily available user applications and interfaces. Programmable clock modulation and internal voltage collection is controlled by a software application. This allows efficient impedance measurement without special test arrangements or special test equipment. The time savings enable aggressive scheduling for design tuning and improves time to market.

One aspect of the present invention provides a system for in situ impedance measurement within a clocked logic type integrated circuit including a plurality of functional partitions in the clocked logic type integrated circuit, the functional partitions having a communication controller and a modulation gate, the modulation gate receiving a clock signal and a modulation signal and generating a modulated clock signal for the functional partition; at least one of the communication controllers receiving an in-band signal and selectively communicating the in-band signal to the other communication controllers; and at least one of the functional partitions having a modulator, the modulator receiving the clock signal and a modulation control signal and generating the modulation signal.

Another aspect of the present invention provides a method of in situ impedance measurement within a clocked logic type integrated circuit with a plurality of functional partitions, the method including receiving a clock signal at the functional partitions; receiving a test instruction at one of the functional partitions, the test instruction including a modulation frequency; modulating the clock signal into a modulation signal corresponding to the modulation frequency at the one of the functional partitions; receiving the modulation signal at the other of the functional partitions; generating a modulated clock signal from the clock signal and the modulation signal at the other of the functional partitions; and operating the other of the functional partitions at the modulation frequency in response to the modulated clock signal.

Another aspect of the present invention provides a computer program product in a computer usable medium for in situ impedance measurement within a clocked logic type integrated circuit with a plurality of functional partitions, the computer program product including computer program code for receiving a clock signal at the functional partitions; computer program code for receiving a test instruction at one of the functional partitions, the test instruction including a modulation frequency; computer program code for modulating the clock signal into a modulation signal corresponding to the modulation frequency at the one of the functional partitions; computer program code for receiving the modulation signal at the other of the functional partitions; computer program code for generating a modulated clock signal from the clock signal and the modulation signal at the other of the functional partitions; and computer program code for operating the other of the functional partitions at the modulation frequency in response to the modulated clock signal.

Another aspect of the present invention provides an information handling system including a processor; and a memory coupled to said processor to store instructions executable by a digital processing apparatus to perform operations to provide in situ impedance measurement within a clocked logic type integrated circuit with a plurality of functional partitions. The operations include receiving a clock signal at the functional partitions; receiving a test instruction at one of the functional partitions, the test instruction including a modulation frequency;

modulating the clock signal into a modulation signal corresponding to the modulation frequency at the one of the functional partitions; receiving the modulation signal at the other of the functional partitions; generating a modulated clock signal from the clock signal and the modulation signal at the other of the functional partitions; and operating the other of the functional partitions at the modulation frequency in response to the modulated clock signal.

The foregoing and other features and advantages of the invention will become further apparent from the following detailed description of the presently preferred embodiments, read in conjunction with the accompanying drawings. The detailed description and drawings are merely illustrative of the invention, rather than limiting the scope of the invention being defined by the appended claims and equivalents thereof.

### BRIEF DESCRIPTION OF THE DRAWINGS

FIG. 1 is a schematic diagram of an existing out-of-band impedance measuring system;

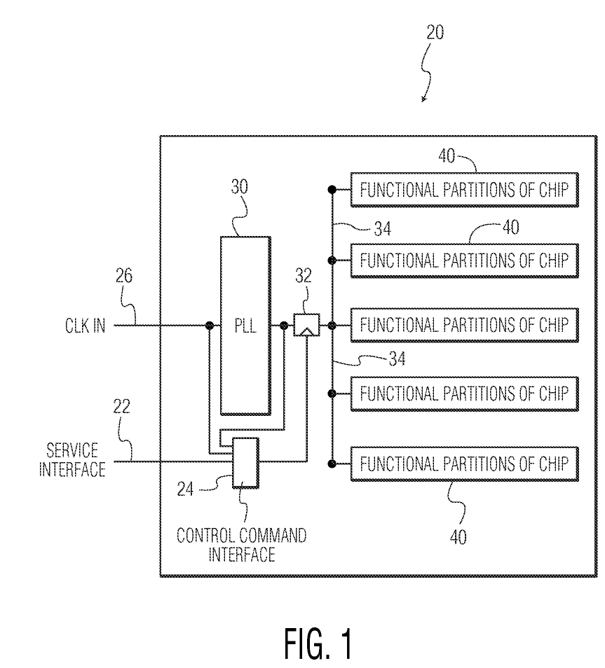

FIG. 2 is a schematic diagram of a clock modulation circuit for an integrated circuit control system made in accordance with the present invention;

FIG. 3 is a flow chart of a method for integrated circuit control of clock modulation performed in accordance with the present invention;

FIG. 4 is a flow chart of a method for in situ impedance measurement using integrated circuit control of clock modulation performed in accordance with the present invention;

FIG. 5 is a block diagram of an integrated circuit control system for in situ impedance measurement;

FIG. 6 is a block diagram of a functional partition of an integrated circuit control system for in situ impedance measurement; and

FIG. 7 is a block diagram of an information handling system for implementing integrated circuit control for in situ impedance measurement in accordance with the present invention.

### DETAILED DESCRIPTION OF PREFERRED EMBODIMENTS

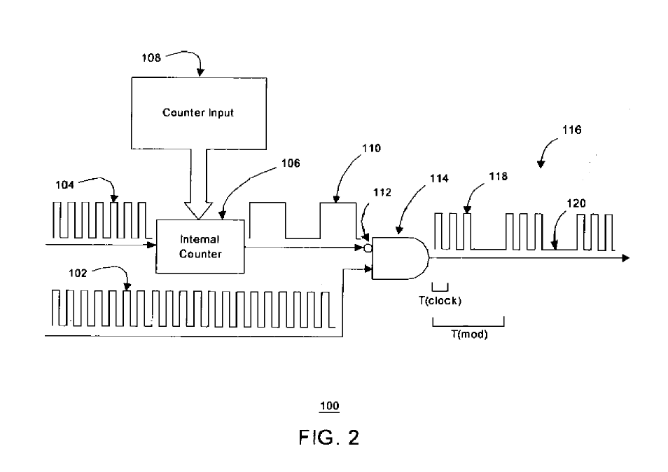

FIG. 2 is a schematic diagram of a clock modulation circuit for an integrated circuit control system made in accordance with the present invention. The programmable clock modulation system 100 receives a first clock signal 102 and a second clock signal 104 and generates a modulated clock signal 118 having a modulation frequency responsive to a modulation control signal 108, which in this example is a counter input. The second clock signal 104 is modulated by modulator 106, which in this example is an internal counter, in response to the modulation control signal 108 to generate modulation signal 110. The modulation signal 110 is inverted by inverter 112 and ANDed with the first clock signal 102 at modulation gate 114 to generate the modulated clock signal 118. The waveform for each of the signals is provided next to its signal path for clarity of illustration. In this example, the modulated clock signal 118 has a clock period T(clock) with a clock frequency F(clock) and a modulation period T(mod) with a modulation frequency F(mod).

The modulated clock signal 118 has a clocked portion 116 and an unclocked portion 120. The clocked portion 116 has a number of clock pulses at the same frequency as the first clock signal 102. The unclocked portion 120 has no clock pulses because the first clock signal 102 is blocked by the low portion of the modulation signal 110 at the modulation gate 114. In this example, the duty cycle of the modulated clock signal 118 is 50 percent, so the duration of the clocked portion 116 is the same as the duration of the unclocked portion 120, i.e., the duration of each is half the modulation period T(mod). The modulation frequency F(mod) of the modulated clock signal 118 can be calculated from the clock frequency F(clock) of the clocked portion 116 and the number of clock pulses (# of clocks) occurring during the clocked portion 116 as follows:

F(mod)=F(clock)/[(# of clocks)*2].

The programmable clock modulation system 100 can be part of a clocked logic type integrated circuit which is to have its impedance measured, such as a microprocessor, a multicore integrated circuit, portion of an integrated circuit, microchip, central processing unit, master control circuit, or other circuit. The first clock signal 102 and second clock signal 104 can be generated from a single clock so that they are identical or can be generated from different clocks. In one embodiment, the first clock signal 102 and second clock signal 104 are provided by the integrated circuit which is to have its impedance measured. In another embodiment, the first clock signal 102 and second clock signal 104 are provided by another integrated circuit. In yet another embodiment, the first clock signal 102 and second clock signal 104 are provided by different cores of a multicore integrated circuit. Those skilled in the art will appreciate that the first clock signal 102 and second clock signal 104 can be in phase, out of phase, or have a predetermined phase offset as desired for a particular application.

The modulator 106 receives modulation control signal 108, such as a programmable modulation control signal, from a computer application. The modulation control signal 108 can be an input provided by a computer application including information about the number of clock cycles and can be received at the modulator 106. In one embodiment, modulator 106 is part of the integrated circuit that is to have its impedance measured. In another embodiment, modulator 106 is external to the integrated circuit. In the example illustrated, the modulator 106 counts the number of cycles of the second clock signal 104 and switches the modulation signal 110 when the number of cycles equals the desired value as determined by the modulation control signal 108. In one embodiment, the modulation control signal 108 is a hexadecimal number between 000 and FFF.

The modulation gate 114 can be any logic gate or combination of logic gates for processing the modulation signal 110 with the first clock signal 102 to provide the desired modulated clock signal 118. Those skilled in the art will appreciate that the use or omission of the inverter 112 and the logical function of the modulation gate 114 are determined as desired for a particular application.

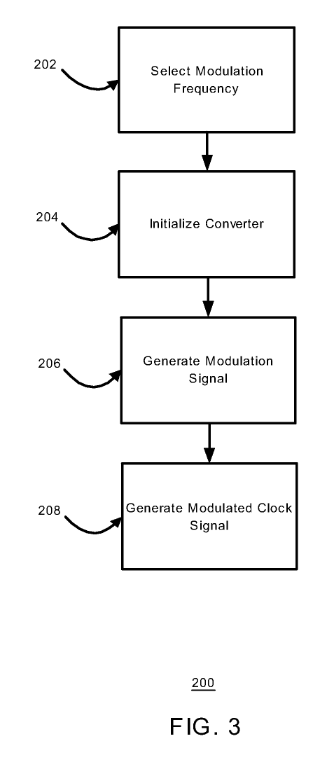

FIG. 3 is a flow chart of a method for integrated circuit control of clock modulation performed in accordance with the present invention. The method 200 includes selecting a modulation frequency 202, initializing a modulator to the modulation frequency 204, generating a modulation signal from the modulator 206, and generating a modulated clock signal within the integrated circuit from a clock signal and the modulation signal 208.

The selecting a modulation frequency 202 can include calculating a number of clock cycles for the predetermined modulation frequency. For the exemplary modulated clock signal 118 of FIG. 2, the number of clock cycles (# of clocks) can be calculated as follows:

# of clocks=F(clock)/[F(mod)*2]

where F(clock) is the clock frequency and F(mod) is the modulation frequency, which are the inverse of the clock period T(clock) and the modulation period T(mod), respectively. Those skilled in the art will appreciate that the calculation of the number of clock cycles depends on the waveform and duty cycle of the clock signals 102, 104 and the modulated clock signal 118 used in a particular application. Once selected, the modulation frequency can be included in a test instruction of an in-band signal and the test instruction received at a functional partition of a clocked logic type integrated circuit.

The selected modulation frequency can have one or more values for the modulation frequency. In one embodiment, the predetermined modulation frequency is a single value. In another embodiment, the predetermined modulation frequency is a predetermined range of modulation frequencies, such as a predetermined range from 100 kHz to 200 MHz. Individual values of the predetermined modulation frequency within the predetermined range of modulation frequencies can be input as a table or calculated in control software. The individual values can be distributed over the predetermined range as desired for a particular application. For example, the individual values can be distributed on a logarithmic scale, a linear scale, or any other scale desired.

Referring to FIG. 3, the initializing a modulator to the modulation frequency 204 can include initializing the modulator to the number of clock cycles provided as modulation control signal from a source. In one embodiment, the modulator is part of a first circuit and the initializing includes initializing the modulator from a circuit other than the first circuit. In one embodiment, the modulation control signal explicitly includes the number of clock cycles, such as a hexadecimal number between 000 and FFF for the number of clock cycles. In another embodiment, the modulation control signal includes clock cycle information specifying the number of clock cycles and the modulator calculates the number of clock cycles from the clock cycle information.

The source can be any source executing a software application and capable of providing the modulation control signal, either in the system being tested or outside the system being tested. In one embodiment, the source executing a software application is the system integrated circuit under test, or alternate processing cores or chips executing a software application and associated with the system integrated circuit under test. The modulation control signal can be provided to the modulator through an inter-integrated circuit (I2C) or other in-band paths. In another embodiment, the source executing a software application is a service processor, a different integrated circuit than the system integrated circuit under test, or other microcontrol chip. The modulation control signal can be provided to the modulator through a network. In one embodiment when the modulator is part of a first circuit, the modulator can be initialized from a circuit other than the first circuit.

The generating a modulation signal from the modulator 206 can include generating a modulation signal from a first clock and a programmable modulation control signal. The first clock can be a clock signal received at functional partitions of a clocked logic type integrated circuit and modulated into the modulation signal corresponding to the modulation frequency at one of the functional partitions.

The generating a modulated clock signal within the integrated circuit from a clock signal and the modulation signal 208 can include generating a modulated clock signal from the modulation signal and a second clock. In one example, the second clock is identical to the first clock and can come from the same source. In one embodiment, the second clock can be the clock signal received at functional partitions of a clocked logic type integrated circuit. The modulation signal can be received at the functional partitions other than the functional partition in which the modulation signal originates. Once the modulated clock signal is generated from the clock signal and the modulation signal, the functional partitions other than the functional partition in which the modulation signal originates can be operated at the modulation frequency in response to the modulated clock signal.

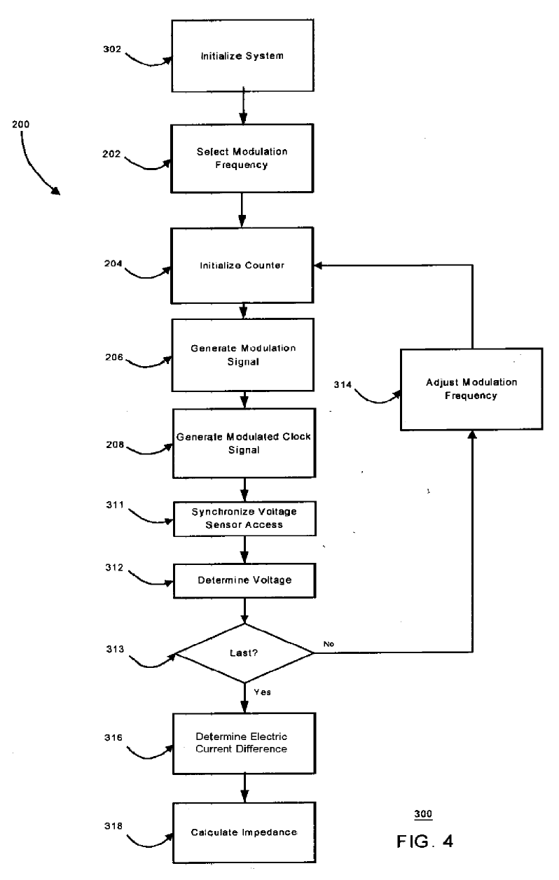

FIG. 4, in which like elements share like reference numbers with FIG. 3, is a flow chart of a method for in situ impedance measurement using integrated circuit control of clock modulation performed in accordance with the present invention. The method 300 employs the method 200 for programmable clock modulation described above.

The system is initialized 302 and enters the method 200, which includes selecting a modulation frequency 202, initializing a modulator to the modulation frequency 204, generating a modulation signal from the modulator 206, and generating a modulated clock signal within the integrated circuit from a clock signal and the modulation signal 208. The voltage sensor access is synchronized with the modulation frequency 311 and the voltage determined 312. In one embodiment, a voltage sensor output is captured and transferred back to a process control application, which computes the voltage.

Those skilled in the art will appreciate that the voltage sensor can monitor any parameter capable of indicating voltage, including performance sensors sensitive to voltage. In one example, the voltage sensor is a voltage sensor as used for clock skew and clock jitter detectors in conjunction with ring oscillators. In another example, the voltage sensor is a clock latency monitor, which sends periodic reference signals into a chain of voltage sensitive circuits, such as inverter delays, monitors those voltage sensitive circuits that detect the presence of the periodic reference signals, and compares the measured value of clock latency to calibrated values. Second order effects, such as those resulting from temperature variation, can also be accounted for. The temperature can be measured with a temperature sensor at about the same time as the voltage measurement and the voltage determined from calibration data including the temperature influence.

The voltage sensor access can be synchronized with the modulation frequency 311 to assure that the instantaneous voltage determination 312 is taken at the same time in the modulated clock signal for all the functional partitions. Those skilled in the aft will appreciate that the synchronization of voltage sensor access with the modulation frequency 311 is optional and can be omitted from particular applications as desired.

It is determined whether the modulation frequency is the last modulation frequency 313. When the modulation frequency is not the last modulation frequency 313, the modulation frequency is adjusted 314 and the method 200 repeated for a next modulation frequency with initializing the modulator to the next modulation frequency 204. When the modulation frequency is the last modulation frequency 313, an electric current difference is measured from the electric currents with the modulated clock signal fully on and fully off 316. Impendence is calculated at each of the modulation frequencies from the electric current difference and the voltage determined at each of the modulation frequencies 318. This determines the impedance characteristic for the integrated circuit.

The initializing the system 302 provides any initial conditions for the impedance measurement. In one embodiment, the initialization sets or resets the modulators. In another embodiment, the initialization shuts down the circuits of the integrated circuit, other than any clocks used in generating the modulated clock signal and voltage determination. In another embodiment, the initialization sets any predetermined modulation frequency or range of modulation frequencies.

The voltage is determined 312 at each modulation frequency and the modulation frequency adjusted 314 when the method 200 is to be repeated for a next modulation frequency. The voltage and impedance of the integrated circuit vary with modulation frequency. The voltage determination can be made for any functional partition (N) that is receiving a modulated clock signal. The voltage is determined for a range of modulation frequencies, with the individual modulation frequencies input as a table or calculated in control software.

When the voltage is determined 312 for the last modulation frequency, an electric current difference is determined from electric currents with the modulated clock signal fully on and fully off 316. In one embodiment, the electric currents are obtained by a query to the power supply over standard power supply interfaces, such as an interface using an I2C protocol, originating from communication controller (P). When the modulated clock signal is fully on, the modulated clock signal is equivalent to the first clock signal 102 as shown in FIG. 2 with the same frequency. When the modulated clock signal is fully off the modulated clock signal is unclocked with zero frequency. The electric current difference is the same for a given clock frequency, i.e., the clock frequency of the first clock signal 102 present in the clocked portion 116 of the modulated clock signal 118, so the electric current difference only has to be measured once for all the modulation frequencies. The electric current difference is determined based on an electric current measurement with the modulated clock signal FULL ON and an electric current measurement with the modulated clock signal FULL OFF. The electric current difference is the difference between the two electric current measurements. Those skilled in the art will appreciate that the electric current difference can be measured any time during the method 300 because the electric current difference is the same for a given clock frequency; one frequency is used for the first clock signal 102 and appears in the clocked portion 116 throughout the method 300. The electrical current demand is a function of leakage, clock duty cycle, and cumulative clock events i.e., how many total times the clock switches within a given time period.

Referring to FIG. 4, impendence is calculated at each of the modulation frequencies from the electric current difference and the voltage determined at each of the modulation frequencies 318. The electric current difference is independent of modulation frequency, so the impedance Z(f) attributable to a modulation frequency f can be determined from the voltage V(f) at the modulation frequency f and the electric current difference ΔI as follows:

Z(f)=V(f)/ΔI

The impedance characteristic for the integrated circuit can be determined by calculating the impedance over the range of modulation frequencies. Those skilled in the art will appreciate that the method 300 over the range of modulation frequencies can be preformed under manual control with each of the modulation frequencies being provided to the modulator manually or under automatic control with each of the modulation frequencies being provided to the modulator by control software. The determination of the impedance characteristic can also be performed manually or by a computer.

In one example, the integrated circuit is an IBM PowerPC microprocessor having a C1 clock and C2 clock. All circuits other than the clock circuits are disabled. The C2 clock can be allowed to run in the background with a small electric current draw. The C1 clock is turned off and on with electric current measurements taken in the off and on states to determine the electric current difference. To generate a modulated clock signal at a predetermined modulation frequency, the C1 clock is modulated with a modulation signal, which is generated by a modulator counting the C2 clock for a number of clock cycles associated with a predetermined modulation frequency. The voltage for the integrated circuit is measured and the impedance at the predetermined modulation frequency is calculated from the voltage and the electric current difference. The number of clock cycles associated with a predetermined modulation frequency can be adjusted over different numbers of clock cycles associated with different predetermined modulation frequencies and a number of voltages measured. The impedance characteristic for the integrated circuit can be determined by calculating the impedance over the range of modulation frequencies.

Those skilled in the art will appreciate that the method 300 can be used for any parameter that varies with frequency and is not limited to voltage. For example, the modulation frequency can be adjusted and temperature characteristic for the integrated circuit determined over a range of modulation frequencies. Other exemplary parameters for certain transistor devices include hysterisis effects, body voltage changes, or the like, as desired for a particular application. In some applications, more than one parameter is determined at each test frequency. For example, when the parameter to be determined is voltage, the temperature can be determined at the same time as the voltage is determined. Voltage sensors can be temperature sensitive, so acquiring the temperature at about the same time as the voltage allows temperature correction of the measured voltage.

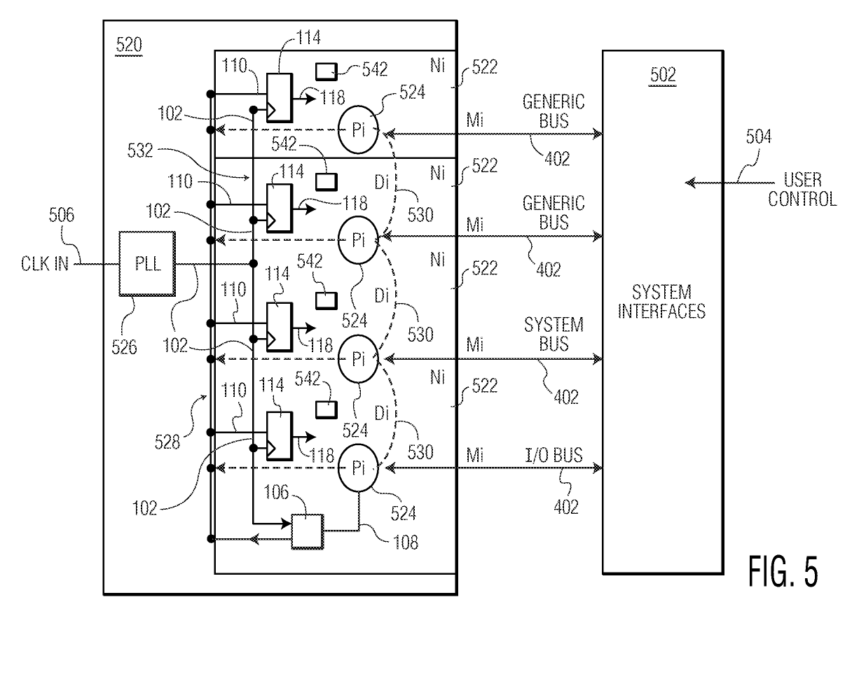

FIG. 5 is a block diagram of an integrated circuit control system for in situ impedance measurement. The integrated circuit control system 500 includes a system interface 502 receiving user control input 504 and a clocked logic type integrated circuit 520, such as a microprocessor, having functional partitions (Ni) 522. The system interface 502 is operably connected to the integrated circuit 520 by one or more processor connection (Mi) 402, such as generic busses, system busses, I/O busses, and the like. The functional partitions 522 include communication controllers 524 and a modulation gate 114, which are functional sub-partitions. The communication controllers 524 can be operably connected to communicate with each other over direct links (Di) 530. The communication controllers 524 can also communicate with each other virtually through the processor connections 402 and the system interface 502.

The functional partitions 522 also include modulation gates 114. The modulation gates 114 are responsive to a non-modulated clock signal 102 and a modulation signal 110 to generate a modulated clock signal 118 for the particular functional partition 522. In this embodiment, the clock signal 102 is generated by a phase locked loop (PLL) 526 from a raw clock signal 506. The clock signal 102 is provided to the functional partitions 522 over a clock bus 532 and the modulation signal 110 is provided to the functional partitions 522 over a modulation bus 528. At least one of the functional partitions 522 has a modulator 106 responsive to a modulation control signal 108 to change the clock signal 102 to the modulation signal 110. In one embodiment, each of the functional partitions 522 has a modulator 106 responsive to a modulation control signal 108 to change the clock signal 102 to the modulation signal 110. During in situ impedance measurement, at least one modulator 106 is active to provide the modulation signal 110 to the functional partitions 522. In one embodiment, the modulator 106 is located within a functional sub-partition of the functional partitions 522, such as being located within the communication controller 524. The modulator 106 is shown outside of the functional sub-partitions for clarity of illustration. The functional partitions 522 include one or more parameter sensors 542, which can be any direct or indirect means for determining a desired parameter. Those skilled in the art will appreciate that the various components within the functional partitions 522 can be located within other components as desired for a particular application. For example, the modulation gate 114, the parameter sensor 542, and/or the modulator 106 can be located within the communication controller 524.

In normal operation, the modulated clock signal 118 is the same as the clock signal 102, i.e., the modulation gate 114 passes the clock signal 102 without any change. In testing operation, the user requests via an in-band signal that certain functional partitions 522 and/or functional sub-partitions be operated at a particular frequency through user control input 504. The in-band signal originates within the normal information handling system and does not require special test connections or equipment. The in-band signal is generated by the normal user applications that are accessible to the user and uses the instructions commonly found in a normal instruction set. The system interface 502 directs the in-band signal including a test instruction over one or more of the processor connections 402 to one or more of the functional partitions 522. The functional partitions 522 can also pass the in-band signal including the test instruction to the other functional partitions 522 over the direct links 530 and/or indirectly over the processor connections 402. The communication controller 524 of the functional partition 522, which includes the modulator 106, receives the in-band signal including the test instruction and generates the modulation control signal 108 corresponding to the desired frequency for the modulated clock signal 118. The modulator 106 receives the modulation control signal 108 and modulates the clock signal 102 into the modulation signal 110 corresponding to the desired frequency for the modulated clock signal 118. The modulation signal 110 is provided to the functional partitions 522 over the modulation bus 528. The modulation gates 114 process the clock signal 102 with the modulation signal 110 to generate a modulated clock signal 118 at the desired test frequency. The functional partitions 522 operate at the desired test frequency, i.e., the modulation frequency, in response to the modulated clock signal 118. The desired parameter, such as voltage, electric current, temperature, or the like can be determined for the functional partition 522 at the desired test frequency and the measured value transmitted from the communication controller 524 to the system interface 502 directly over one of the processor connections 402, or indirectly over the direct links 530 and through one of the processor connections 402. The testing can continue with another desired test frequency or can finish.

The in-band signal including the test instruction through the user control input 504 can specify groups of tests to be run, such as ranges of functional partitions 522 over ranges of desired test frequencies, or can specify a particular test, such as a particular functional partition 522 at a particular test frequency. The in-band signal can determine which of the functional partitions are clocked with the modulated clock signal. The in-band signal on the user control input 504 can originate in a user application or the operating system. The testing process can start with any of the functional partitions 522 having a modulator 106. The functional partitions 522 running the testing process and actively connected through the processor connection 402 to the system interface 502 does not modulate the modulated clock signal 118 for itself, but the modulated clock signal 118 remains the same frequency as the clock signal 102. When more than one of the functional partitions 522 have a modulator 106, the test instruction can include an address of a functional partition to determine which of the functional partitions has the modulator generating the modulation signal, in addition to including the modulation frequency.

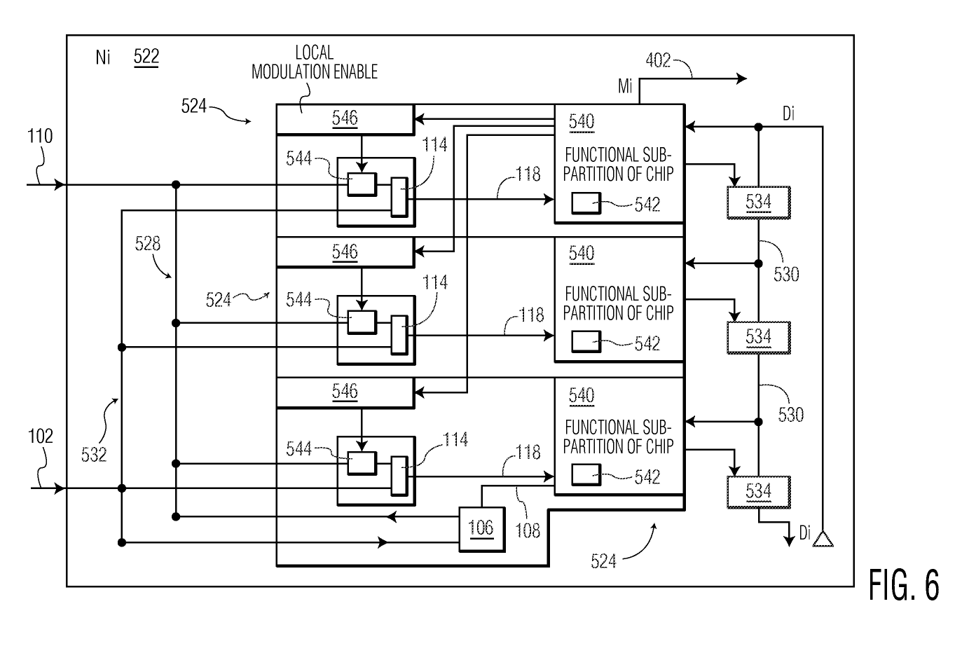

FIG. 6, in which like elements share like reference numbers with FIG. 5, is a block diagram of a functional partition of an integrated circuit control system for in situ impedance measurement In this example, the functional partition 522 includes a number of communication controllers 524, each having a functional sub-partition 540. When the functional partition includes a number of functional sub-partitions, the functional sub-partitions can be modulated or not modulated independently of each other depending on the local modulation enable signal for each of the functional sub-partitions.

Each of the functional sub-partitions 540 includes one or more parameter sensors 542, which can be any direct or indirect means for determining a desired parameter. For example, voltage as the desired parameter can be determined directly when the parameter sensor 542 is a voltage sensor or can be determined indirectly when the parameter sensor 542 is a combination of temperature and performance sensors sensitive to voltage. The temperature can be measured with a temperature sensor at about the same time as the voltage measurement and the voltage determined from calibration data including the temperature influence. At least one of the functional sub-partitions 540 includes a processor connection 402. In one embodiment, the processor connection 402 is used to query to the power supply to determine the electric current. In this example, the direct links 530 are connected by switches 534 that can be used to bypass certain of the communication controllers 524 as desired.

In this example, the communication controllers 524 include a local modulation enable function. The communication controllers 524 include an enable gate 544 between the modulation bus 528 and the modulation gate 14. The enable gate 544 is responsive to a local modulation enable signal 546 from at least one of the functional sub-partitions 540 to block or pass the modulation signal 110 to the modulation gate 114. In testing operation, a test instruction to the functional sub-partitions 540 over the processor connections 402 and/or the direct links 530 can enable or disable the modulation signal 110 from reaching the modulation gate 114, so that some of the functional sub-partitions 540 can be operated at the desired test frequency and others of the functional sub-partitions 540 can be operated at the normal operating frequency.

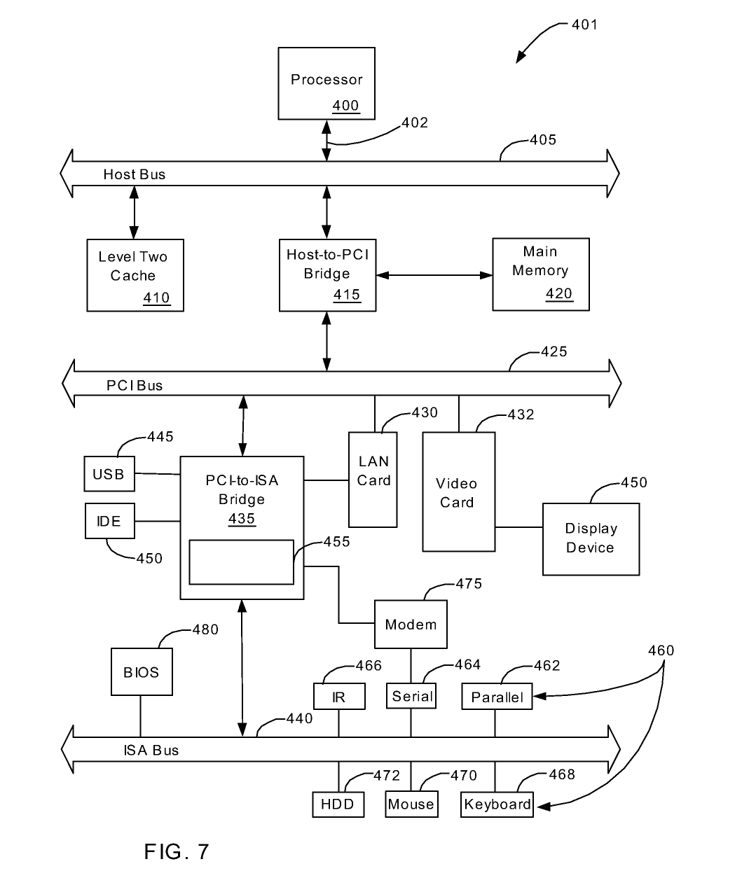

FIG. 7 is a block diagram of an information handling system for implementing integrated circuit control for in situ impedance measurement in accordance with the present invention. The information handling system 401 is a simplified example of a computer system capable of performing the operations described herein. The information handling system 401 includes processor 400 which is coupled to host bus 405 with a processor connection 402. A level two (L2) cache memory 410 is also coupled to the host bus 405. Host-to-PCI bridge 415 is coupled to main memory 420, includes cache memory and main memory control functions, and provides bus control to handle transfers among PCI bus 425, processor 400, L2 cache 410, main memory 420, and host bus 405. The PCI bus 425 provides an interface for a variety of devices including, for example, LAN card 430 and/or video card 432. The video card 432 is operably connected to a display device 490, such as a liquid crystal display (LCD), a cathode ray tube (CRT) display, a projection display, or the like. Those skilled in the art will appreciate that the video card 432 can be attached to other types of busses, such as an AGP or a PCI Express bus, as desired for a particular application.

PCI-to-ISA bridge 435 provides bus control to handle transfers between the PCI bus 425 and ISA bus 440, universal serial bus (USB) functionality 445, IDE device functionality 450, power management functionality 455, and can include other functional elements not shown, such as a real-time clock (RTC), DMA control, interrupt support, and system management bus support. Peripheral devices and input/output (I/O) devices can be attached to various interfaces 460 (e.g., parallel interface 462, serial interface 464, infrared (IR) interface 466, keyboard interface 468, mouse interface 470, and fixed disk (HDD) 472) coupled to ISA bus 440. Alternatively, a super I/O controller (not shown) can be attached to the ISA bus 440 to accommodate many I/O devices.

BIOS 480 is coupled to ISA bus 440, and incorporates the necessary processor executable code for a variety of low-level system functions and system boot functions. The BIOS 480 can be stored in any computer readable medium, including magnetic storage media, optical storage media, flash memory, random access memory, read only memory, and communications media conveying signals encoding the instructions (e.g., signals from a network). In order to attach information handling system 401 to another computer system to copy files over a network, LAN card 430 is coupled to PCI bus 425 and to PCI-to-ISA bridge 435. Similarly, to connect computer system 401 to an ISP to connect to the Internet using a telephone line connection, modem 475 is connected to serial port 464 and PCI-to-ISA Bridge 435.

While the computer system described in FIG. 7 is capable of executing the invention described herein, this computer system is simply one example of a computer system. Another such example is routing of communication controller commands between integrated circuits in a multi-processor or multi-node configuration over a system interconnection bus. Those skilled in the art will appreciate that many other computer system designs are capable of performing the invention described herein.

One of the preferred implementations of the invention is an application, namely, a set of instructions (program code) in a code module which may, for example, be resident in the random access memory of the computer. Until required by the computer, the set of instructions may be stored in another computer memory, for example, on a hard disk drive, or in removable storage such as an optical disk (for eventual use in a CD ROM) or floppy disk (for eventual use in a floppy disk drive), or downloaded via the Internet or other computer network. Thus, the present invention may be implemented as a computer program stored on a computer readable medium and executable by a digital processing apparatus to perform operations to display data. In addition, although the various methods described are conveniently implemented in a general purpose computer selectively activated or reconfigured by software, one of ordinary skill in the art would also recognize that such methods maybe carried out in hardware, in firmware, or in more specialized apparatus constructed to perform the required method steps.

While the embodiments of the invention disclosed herein are presently considered to be preferred, various changes and modifications can be made without departing from the spirit and scope of the invention. The scope of the invention is indicated in the appended claims, and all changes that come within the meaning and range of equivalents are intended to be embraced therein.

1. A system for in situ impedance measurement within a clocked logic type integrated circuit, the system comprising:
a plurality of functional partitions in the clocked logic type integrated circuit, the functional partitions having a communication controller and a modulation gate, the modulation gate receiving a clock signal and a modulation signal and generating a modulated clock signal for the functional partition;
at least one of the communication controllers receiving an in-band signal and generating a modulation control signal; and
at least one of the functional partitions having a modulator, the modulator receiving the clock signal and the modulation control signal and generating the modulation signal.

2. The system of claim 1 wherein the in-band signal determines which of the functional partitions are clocked with the modulated clock signal.

3. The system of claim 1 wherein more than one of the functional partitions has a modulator and the in-band signal determines which of the functional partitions has the modulator generating the modulation signal.

4. The system of claim 1 wherein at least one of the functional partitions have a parameter sensor to determine a parameter at the functional partition, the parameter being selected from the group consisting of voltage, electric current, and temperature.

5. The system of claim 1 wherein at least one of the communication controllers is linked to selectively communicate the in-band signal to the other communication controllers by connections selected from the group consisting of processor connections and direct links.

6. The system of claim 1 wherein at least one of the communication controllers comprises a plurality of functional sub-partitions, at least one of the functional sub-partitions providing a local modulation enable signal to an enable gate between the modulation bus and the modulation gate to disable the modulation signal from reaching the modulation gate.

7. A method of in situ impedance measurement within a clocked logic type integrated circuit with a plurality of functional partitions, the method comprising:
receiving a clock signal at the functional partitions;
receiving a test instruction at one of the functional partitions, the test instruction including a modulation frequency;
modulating the clock signal into a modulation signal corresponding to the modulation frequency at the one of the functional partitions;
receiving the modulation signal at the other of the functional partitions;
generating a modulated clock signal from the clock signal and the modulation signal at the other of the functional partitions; and
operating the other of the functional partitions at the modulation frequency in response to the modulated clock signal.

8. The method of claim 7 further comprising receiving the test instruction at the plurality of the functional partitions, the test instruction further including an address for the one of the plurality of functional partitions assigned to convert the clock signal to the modulation signal corresponding to the modulation frequency.

9. The method of claim 7 further comprising:
determining an electric current difference for at least one of the functional partitions between the modulated clock signal being FULL OFF and FULL ON;
determining a voltage for the at least one of the functional partitions; and
determining impedance for the at least one of the functional partitions from the electric current difference and the voltage.

10. The method of claim 9 further comprising:
receiving test instructions at one of the functional partitions, each of the test instructions including one of a plurality of predetermined modulation frequencies;
determining a plurality of voltages, each of the plurality of voltages being associated with one of the plurality of predetermined modulation frequencies;
determining a plurality of impedances for the clocked logic type integrated circuit from the electric current difference and the plurality of voltages; and
determining an impedance characteristic for the functional partition from the plurality of impedances and the plurality of predetermined modulation frequencies.

11. The method of claim 9, the determining a voltage further comprising synchronizing voltage sensor access with the modulation frequency.

12. A computer program product in a computer usable medium for in situ impedance measurement within a clocked logic type integrated circuit with a plurality of functional partitions, the computer program product comprising:
computer program code for receiving a clock signal at the functional partitions;
computer program code for receiving a test instruction at one of the functional partitions, the test instruction including a modulation frequency;
computer program code for modulating the clock signal into a modulation signal corresponding to the modulation frequency at the one of the functional partitions;
computer program code for receiving the modulation signal at the other of the functional partitions;
computer program code for generating a modulated clock signal from the clock signal and the modulation signal at the other of the functional partitions; and
computer program code for operating the other of the functional partitions at the modulation frequency in response to the modulated clock signal.

13. The computer program product of claim 12 further comprising computer program code for receiving the test instruction at the plurality of the functional partitions, the test instruction further including an address for the one of the plurality of functional partitions assigned to convert the clock signal to the modulation signal corresponding to the modulation frequency.

14. The computer program product of claim 12 further comprising:
computer program code for determining an electric current difference for at least one of the functional partitions between the modulated clock signal being FULL OFF and FULL ON;
computer program code for determining a voltage for the at least one of the functional partitions; and
computer program code for determining impedance for the at least one of the functional partitions from the electric current difference and the voltage.

15. The computer program product of claim 14 further comprising:
computer program code for receiving test instructions at one of the functional partitions, each of the test instructions including one of a plurality of predetermined modulation frequencies;
computer program code for determining a plurality of voltages, each of the plurality of voltages being associated with one of the plurality of predetermined modulation frequencies;
computer program code for determining a plurality of impedances for the clocked logic type integrated circuit from the electric current difference and the plurality of voltages; and
computer program code for determining an impedance characteristic for the functional partition from the plurality of impedances and the plurality of predetermined modulation frequencies.

16. The computer program product of claim 14, the computer program code for determining a voltage further comprising computer program code for synchronizing voltage sensor access with the modulation frequency.

17. An information handling system comprising:
a processor; and
a memory coupled to said processor to store instructions executable by a digital processing apparatus to perform operations to provide in situ impedance measurement within a clocked logic type integrated circuit with a plurality of functional partitions, the operations comprising;
receiving a clock signal at the functional partitions;
receiving a test instruction at one of the functional partitions, the test instruction including a modulation frequency;
modulating the clock signal into a modulation signal corresponding to the modulation frequency at the one of the functional partitions;
receiving the modulation signal at the other of the functional partitions;
generating a modulated clock signal from the clock signal and the modulation signal at the other of the functional partitions; and
operating the other of the functional partitions at the modulation frequency in response to the modulated clock signal.

18. The system of claim 17, the operations further comprising receiving the test instruction at the plurality of the functional partitions, the test instruction further including an address for the one of the plurality of functional partitions assigned to convert the clock signal to the modulation signal corresponding to the modulation frequency.

19. The system of claim 17, the operations further comprising:
determining an electric current difference for at least one of the functional partitions between the modulated clock signal being FULL OFF and FULL ON;
determining a voltage for the at least one of the functional partitions; and
determining impedance for the at least one of the functional partitions from the electric current difference and the voltage.

20. The system of claim 19, the operations further comprising;
receiving test instructions at one of the functional partitions, each of the test instructions including one of a plurality of predetermined modulation frequencies;
determining a plurality of voltages, each of the plurality of voltages being associated with one of the plurality of predetermined modulation frequencies;
determining a plurality of impedances for the clocked logic type integrated circuit from the electric current difference and the plurality of voltages; and
determining an impedance characteristic for the functional partition from the plurality of impedances and the plurality of predetermined modulation frequencies.
